(19) United States
(12) Patent Application Publication
(10) Pub. No.: US 2008/0042117 A1
(43) Pub. Date: Feb. 21, 2008

(54) PHASE-CHANGE MEMORY AND FABRICATION METHOD THEREOF

(75) Inventor: Hong-Hui Hsu, Changhua County (TW)

Correspondence Address: QUINTERO LAW OFFICE, PC, 2210 MAIN STREET, SUITE 200, SANTA MONICA, CA, 90405, US

(73) Assignees: INDUSTRIAL TECHNOLOGY RESEARCH INSTITUTE, HSINCHU (TW); POWERCHIP SEMICONDUCTOR CORP., HSIN-CHU (TW); NANYA TECHNOLOGY CORPORATION, TAOYUAN (TW); PROMOS TECHNOLOGIES INC., HSINCHU (TW); WINBOND ELECTRONICS CORP., HSINCHU (TW)

(21) Appl. No.: 11/558,880

(22) Filed: Nov. 10, 2006

(30) Foreign Application Priority Data
Aug. 15, 2006 (TW) TW95129893

(51) Int. Cl. H01L 29/04

(52) U.S. Cl. 257/3

(57) ABSTRACT

A phase-change memory and fabrication method thereof are disclosed. The phase-change memory comprises a first dielectric layer with a first opening formed on a substrate. A first electrode is filled into the first opening. A second dielectric pillar is formed on the first electrode. A first conducting layer is formed on the sidewalls of the second dielectric pillar, electrically connecting the first electrode. A third dielectric layer is formed on the substrate, exposing the top surface of the first conducting layer. A phase-change layer is formed on the third dielectric layer and directly contacts the top surface of the first conducting layer. A fourth dielectric layer, having a second opening exposing the top surface of the phase-change layer, is formed on the substrate. A second conducting layer is filled into the second opening, electrically connecting to a second electrode.

### BACKGROUND OF THE INVENTION

1. Field of the Invention

The invention relates to a memory element, and more particularly to a phase-change memory element.

2. Description of the Related Art

Electronic equipment typically employs various types of memory, such as DRAM, SRAM and flash memory, or a combination, based on the requirements of the application, the operating speed, the memory size and the cost considerations of the equipment. Current developments in the memory technology field include FeRAM, MRAM and phase-change memory. Among these phase-change memory is slated for future mass manufacture.

Phase-change memory elements are non-volatile, have high density, high contrast, high cycling, and low power-consumption, thus, they are industry semiconductor of choice. Particularly, since the manufacturing process of phase-change memory elements is compatible with the CMOS manufacturing process, phase-change memory elements can be fabricated as a detached or embedded memory cell.

Storing data in a phase-change memory element typically requires high current density. Unfortunately, high current can lead to unwanted high power consumption. Reduced power consumption can be achieved by increasing the contact resistance between the phase-change layer and the electrode. Many methods for reducing contact area have been proposed to increase resistance and reduce power consumption. As PRAMs (Phase-change RAMs) become smaller, however, forming small contacts to the phase-change layer pattern generally becomes increasingly difficult. This difficulty arises due to the reduction of design rules limiting photolithography processes for defining contact images on photoresist layers. The limited photolithography processes may further decrease the flexibility of the PRAM fabrication processes.

In disclosing a method of making a programmable resistance memory element with a small contact area, U.S. Pat. No. 6,746,892 to Heon Lee, et. al presents one solution for increasing contact resistance, please refer to FIG. 1. First, a dielectric layer is formed on the substrate 11. Next, the dielectric layer is etched to form taper-shaped dielectric salients 13. Next, an electrode layer 15 is conformably formed on the taper-shaped dielectric salients 13. Next, an insulation layer 17 formed on the described structure. Next, the insulation layer 17 is etched back to expose the electrode layer 15 formed on the tip of the taper-shaped dielectric salient 13 from the insulation layer 17.

Next, a phase-change layer 19 is formed on the substrate 11 to contact the electrode layer 15 formed on the tip of the taper-shaped dielectric salient 13, resulting in reducing the contact area between phase-change layer 19 and electrode layer 15. Finally, top electrode layers 23 are formed on the phase-change layer 19, separated by an intermetal dielectric layer 21.

The conventional phase-change memory element has reduced contact area between the phase-change layer and electrode layer. The process for forming taper-shaped dielectric salients with tip, however, is complicated and difficult. Further, the shape of the contact electrode is difficult to control, and it is extremely difficult to make all the profiles of the contact electrodes formed on the tip of the taper-shaped dielectric salients uniform.

Thus, a less complicated fabrication process for phase-change memory elements with reduced contact area is desirable.

### BRIEF SUMMARY OF THE INVENTION

An exemplary embodiment of a phase-change memory element comprises a first dielectric layer with a first opening formed on a substrate. A first electrode is filled into the first opening. A second dielectric pillar is formed on the first electrode. A first conducting layer is formed on the sidewalls of the second dielectric pillar, electrically connected to the first electrode. A third dielectric layer is formed on the substrate, exposing the top surface of the first conducting layer. A phase-change layer is formed on the third dielectric layer and directly contacts the top surface of the first conducting layer. A fourth dielectric layer, having a second opening exposing the top surface of the phase-change layer, is formed on the substrate. A second conducting layer is filled into the second opening, electrically connecting to a second electrode.

Methods of manufacturing phase-change memory elements are also provided. An exemplary embodiment of a method comprises the following steps. A substrate is provided. A first dielectric layer with a first opening is formed on the substrate. A first electrode is filled into the first opening. A second dielectric pillar is formed on the first electrode. A first conducting layer is conformably formed on the substrate to cover the sidewalls and top surface of the second dielectric layer. The first conducting layer is etched by anisotropic etching, exposing the top surface of the second dielectric pillar. A third dielectric layer is formed on the substrate. The third dielectric layer is planarized, exposing the top surface of the first conducting layer. A phase-change layer is formed on the third dielectric layer, wherein the phase-change layer directly contacts the top surface of the first conducting layer. A fourth dielectric layer, having a second opening exposing the top surface of the phase-change layer, is formed on the third dielectric layer and the phase-change layer. A second conducting layer is filled into the second opening, electrically connecting the phase-change layer. A second electrode electrically connects the second conducting layer.

According to another exemplary embodiment of the invention, the method of manufacturing phase-change memory element comprises the following steps. A substrate is provided. A first dielectric layer with a first opening is formed on the substrate. A first electrode is filled into the first opening. A conducting pillar is formed on the first electrode via a second dielectric layer. A third dielectric layer is formed on the substrate. The third dielectric layer is planarized, exposing the top surface of the conducting pillar. A phase-change layer is formed on the third dielectric layer, wherein the phase-change layer directly contacts to the top surface of the conducting pillar. A fourth dielectric layer, having a second opening exposing the top surface of the phase-change layer, is formed on the third dielectric layer and the phase-change layer. A second conducting layer is filled into the second opening, electrically connecting the phase-change layer. A second electrode electrically connects the second conducting layer.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 is a cross section of a conventional phase-change memory element.

FIGS. 2a-2m are cross sections showing a method of fabricating a phase-change memory element according to an embodiment of the invention.

FIG. 3 is a top view of the phase-change memory element according to FIG. 2f.

FIGS. 4a-4j are cross sections of showing a method of fabricating a phase-change memory element according to another embodiment of the invention.

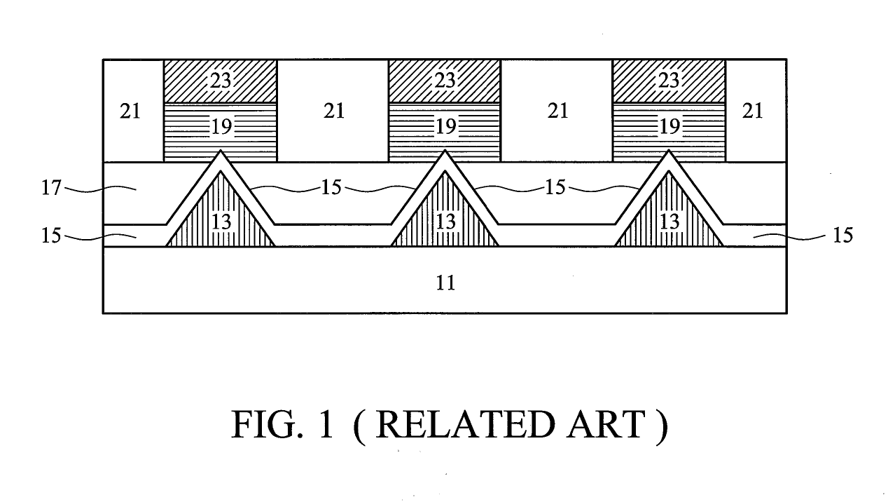

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

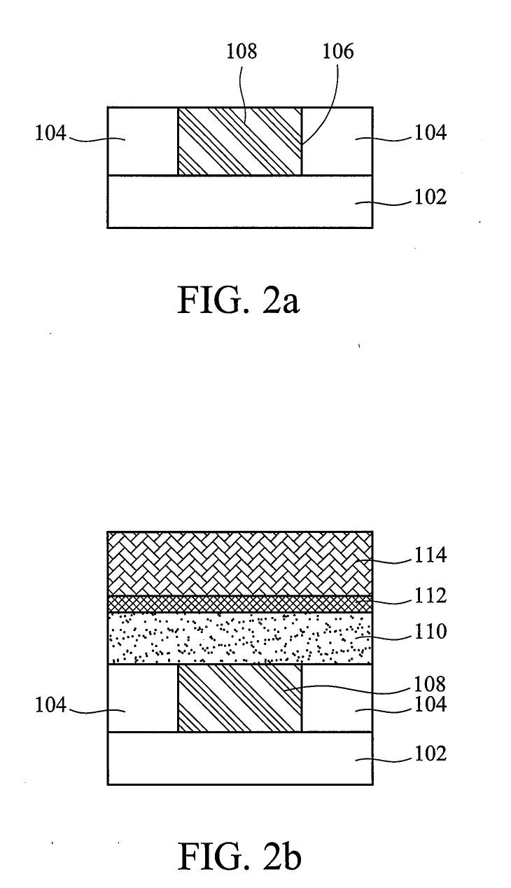

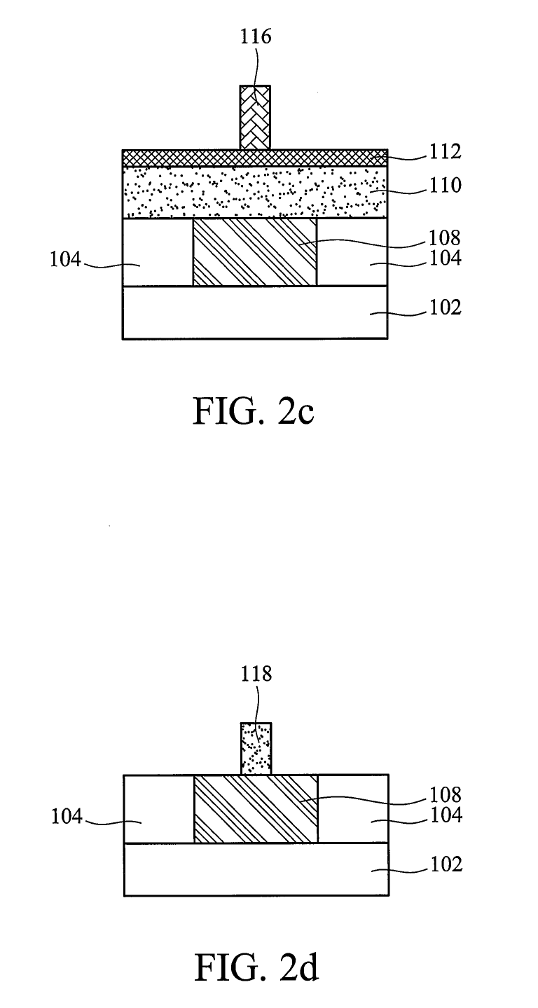

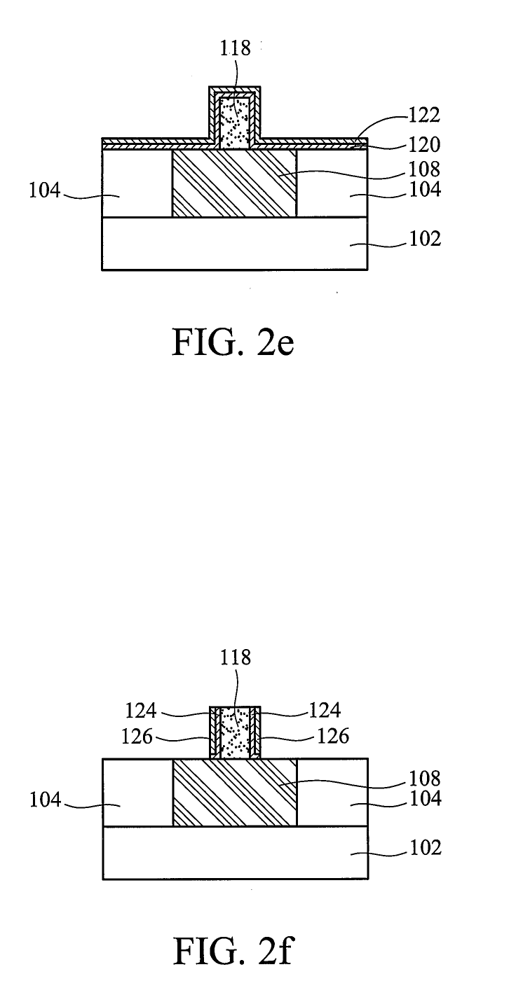

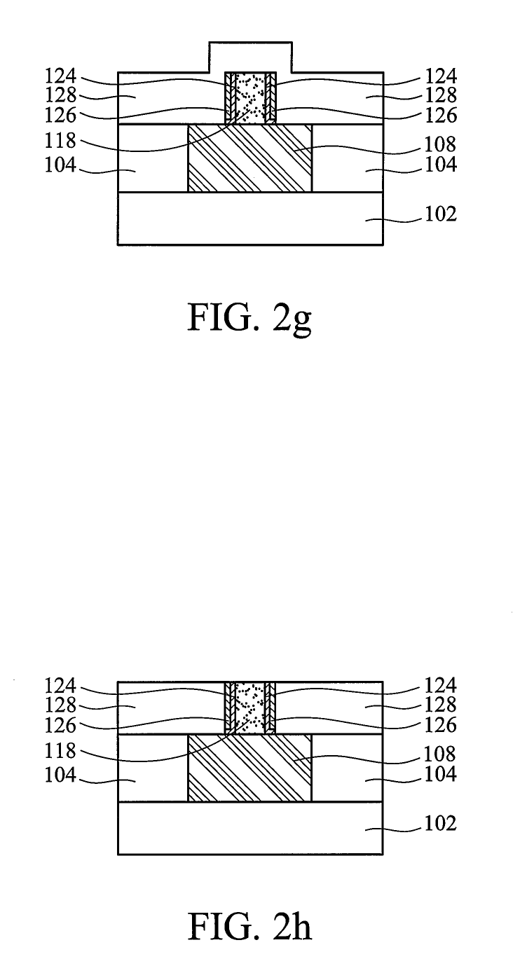

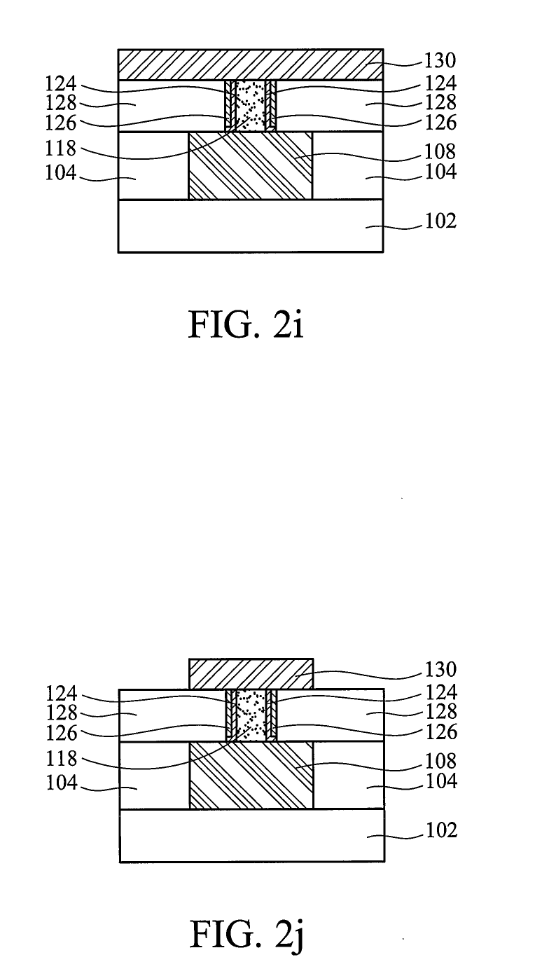

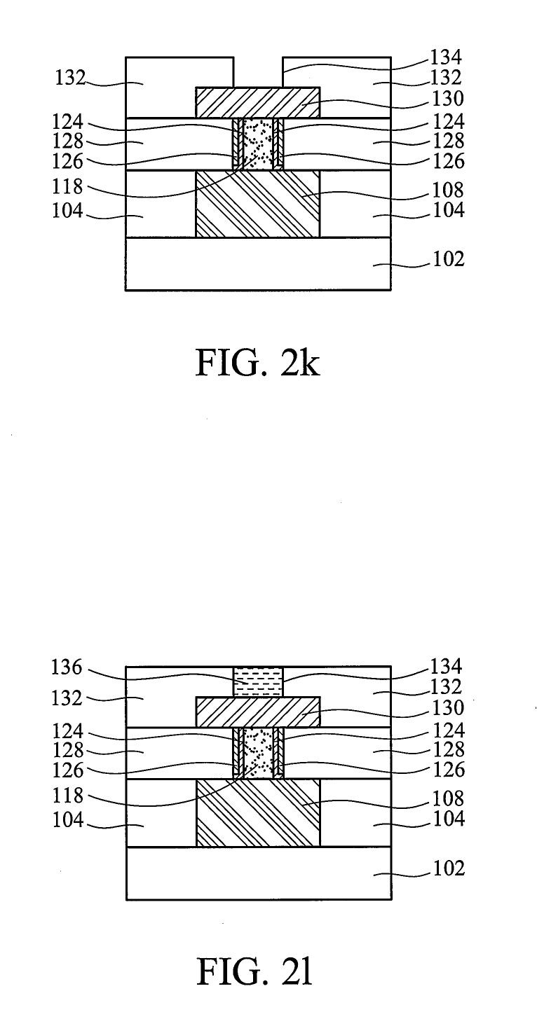

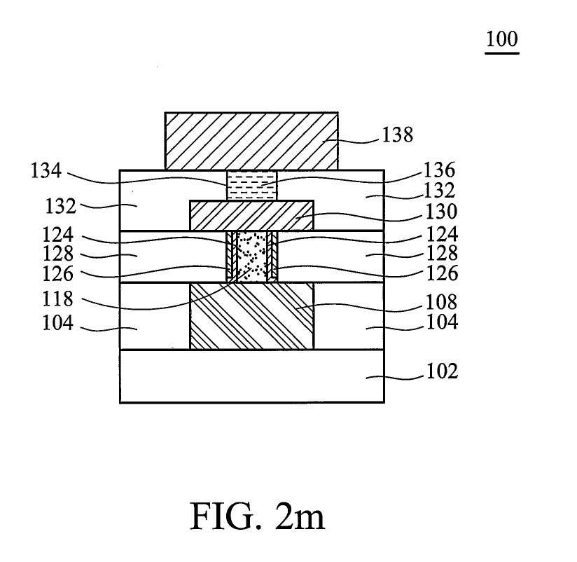

FIGS. 2a to 2m are sectional diagrams illustrating the manufacturing process of the phase-change memory element 100 of an embodiment of the invention.

First, referring to FIG. 2a, a first dielectric layer 104 with a first opening 106 is formed on a substrate 102. Next, a metal layer is filled into the first opening 106 serving as a first electrode 108. Particularly, the substrate 102 can be a substrate employed in a semiconductor process, such as silicon substrate. The substrate 102 can be a substrate comprising a complementary metal oxide semiconductor (CMOS) circuit, isolation structure, diode, or capacitor. The accompanying drawings show the substrate 102 in a plain rectangle in order to simplify the illustration. The first dielectric layer 104 can be silicon-containing compound, such as silicon nitride or silicon oxide. Suitable material for the first electrode can be Al, W, Mo, TiN, or TiW.

Next, referring to FIG. 2b, a second dielectric layer 110, a bottom anti-reflective coating 112, and a photoresist layer 114 are sequentially formed on the substrate 102. In this embodiment, the second dielectric layer 110 can be a silicon-containing compound, such as silicon nitride or silicon oxide.

Next, referring to FIG. 2c, the photoresist layer 114 is patterned by a photolithography process and then trimmed by a trimming process to form a photoresist pillar 116 with a diameter of not more than 100 nm. It should be noted that, the photoresist pillar 116 is formed directly above the first electrode 108.

According to the invention, the trimming process is not limited to certain process, and can be dry trimming process (such as plasma trimming process) or solution trimming process.

Next, referring to FIG. 2d, the second dielectric layer 110 is etched to form a second dielectric pillar 118 with the photoresist pillar 116 as a mask, wherein the diameter of the second dielectric pillar 118 is not more than 100 nm. In this step, the photoresist pillar 116 and bottom anti-reflective coating 112 are removed by simultaneous etching. Specifically, the second dielectric pillar 118 is formed directly above the first electrode 108 and contacts with the first electrode 108.

As a feature and a key aspect, the photoresist layer is patterned by a photolithography process and trimmed by a trimming process, resulting in a photoresist pattern with a diameter less than the resolution limit of the photolithography process. The, the second dielectric layer 110 is then etched with the reduced photoresist pattern as a mask, obtaining a second dielectric pillar 118.

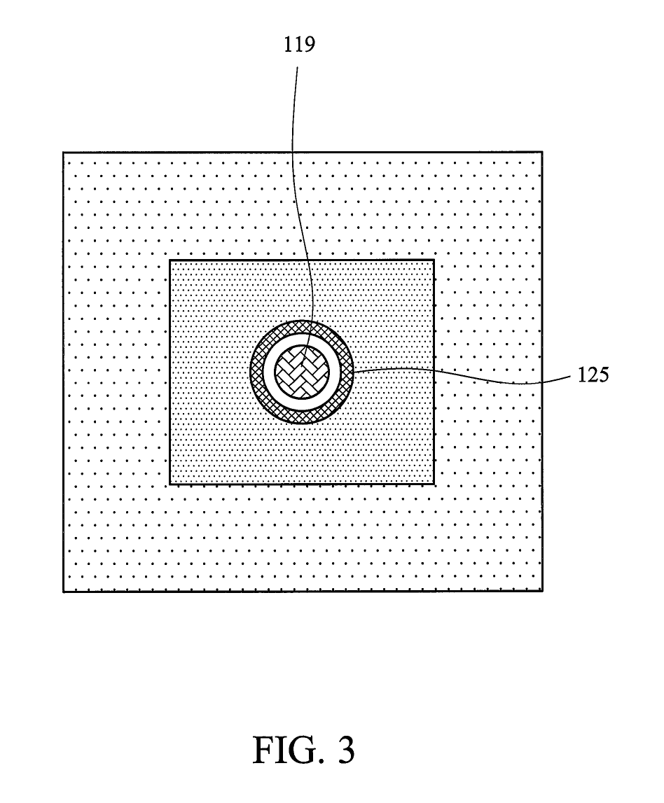

Next, referring to FIG. 2e, a first conducting layer 120 and a third dielectric layer 122 are conformably formed on the substrate 102, covering the second dielectric pillar 118. Next, referring to FIG. 2f, the first conducting layer 120 and the third dielectric layer 122 are etched by an anisotropic etching, exposing the top surface 119 of the second dielectric pillar 118. FIG. 3 shows the top view of FIG. 2f illustrates that the remaining first conducting layer 124 and remaining third dielectric layer 126 surrounds the sidewalls of second dielectric pillar 118. It should be noted that the top surface 125 of the first conducting layer 124 is exposed by the third dielectric layer 122. Suitable material for the first conducting layer can be W, TiN, TiAlN, Ta, TaN, poly-Si, TiSiN, TaSiN, or combinations thereof, and the third dielectric layer can be silicon-containing compound. Particularly, the contact area between the first conducting layer and the phase-change layer depends on the thickness of the first conducting layer. Generally, the first conducting layer (metal layer) can be formed with a thickness of less than 50 nm (such as 20 nm or 10 nm) by a semiconductor process, resulting in a reduced phase-change layer contact area.

Next, referring to FIG. 2g, a fourth dielectric layer 128 is formed on the substrate 102, completely covering the second dielectric pillar 118, the remaining first conducting layer 124 and remaining third dielectric layer 126. Next, referring to FIG. 2h, the fourth dielectric layer 128 is planarized to expose the top surface of the first conducting layer, wherein the planarization can be chemical mechanical polishing. The fourth dielectric layer 128 can be silicon-containing compound such as silicon nitride or silicon oxide.

Next, referring to FIG. 2i, a phase-change layer 130 is formed on the fourth dielectric layer 128 to directly contact and electrically connect to the top surface of the remaining first conducting layer 124. Next, referring to FIG. 2j, the phase-change layer 130 is patterned to form a patterned phase-change layer 130. The phase-change layer can comprise In, Ge, Sb, Te or combinations thereof, such as GeSbTe or InGeSbTe.

Next, referring to FIG. 2k, a fifth dielectric layer 132 is formed on the fourth dielectric layer 128 and the phase-change layer 130, wherein the fifth dielectric layer 132 having a second opening 134 exposes the top surface of the phase-change layer 130. The fifth dielectric layer 132 can be silicon-containing compound, such as silicon nitride or silicon oxide.

Next, referring to FIG. 21, a second conducting layer 136 is formed on and fills the second opening, electrically connecting the phase-change layer 130. Finally, referring to FIG. 2m, a second electrode 138 is formed to electrically connect to the second conducting layer 136. Suitable material for the second electrode 138 can be Al, W, Mo, TiN, or TiW. The second conducting layer 136 can be W, TiN, TiAlN, Ta, TaN, poly-Si, TiSiN, TaSiN, or combinations thereof.

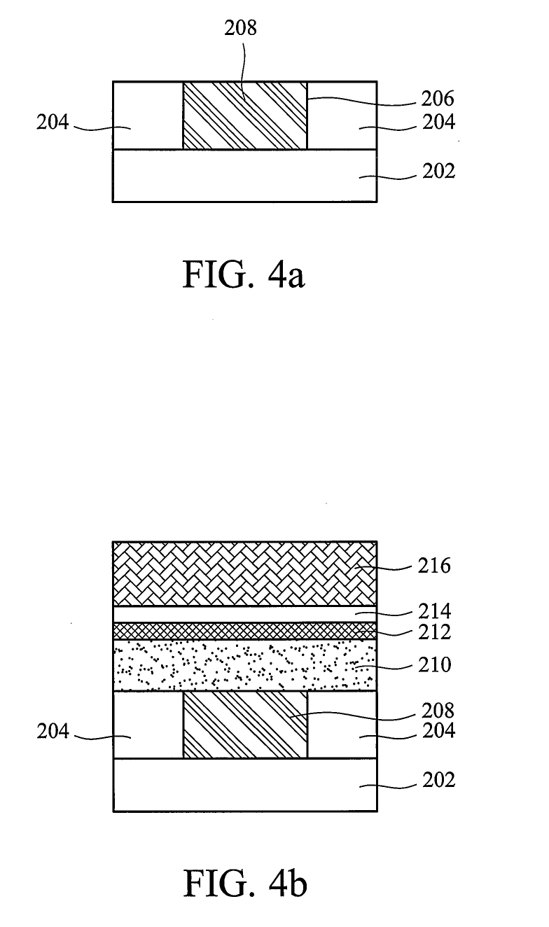

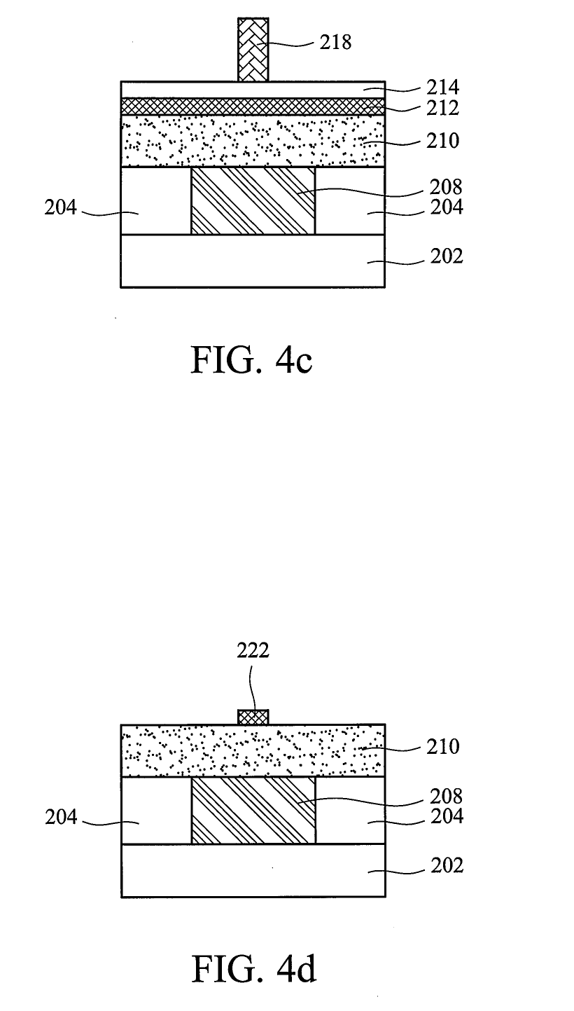

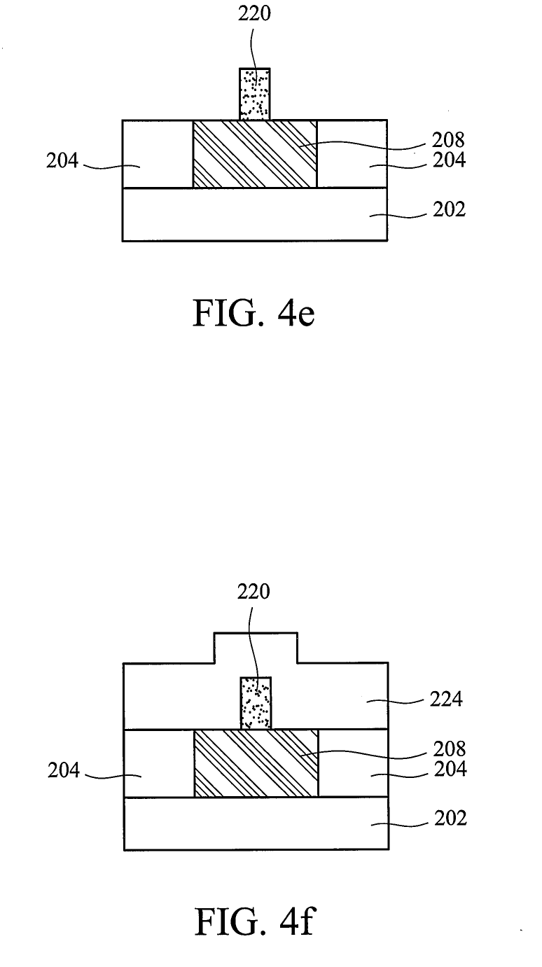

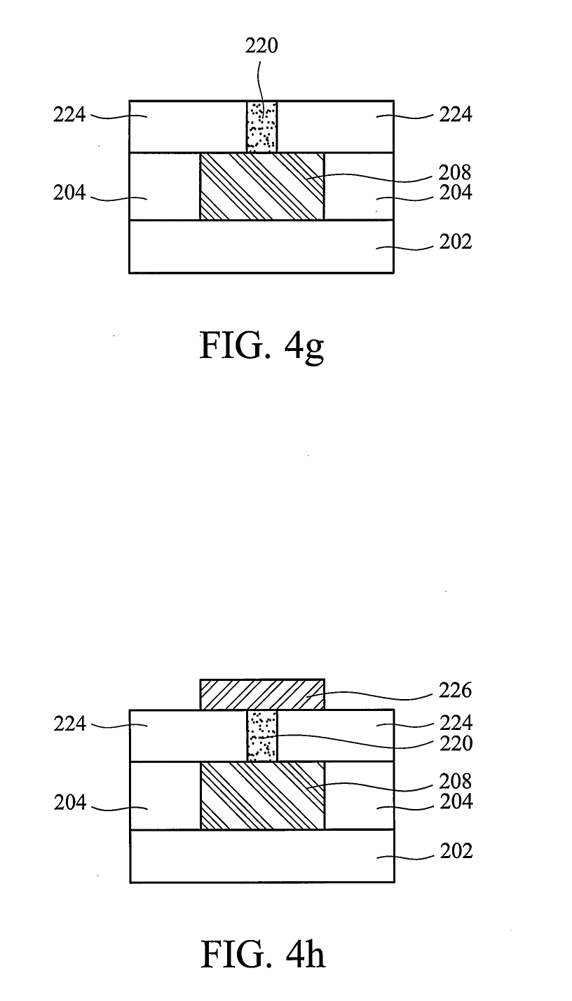

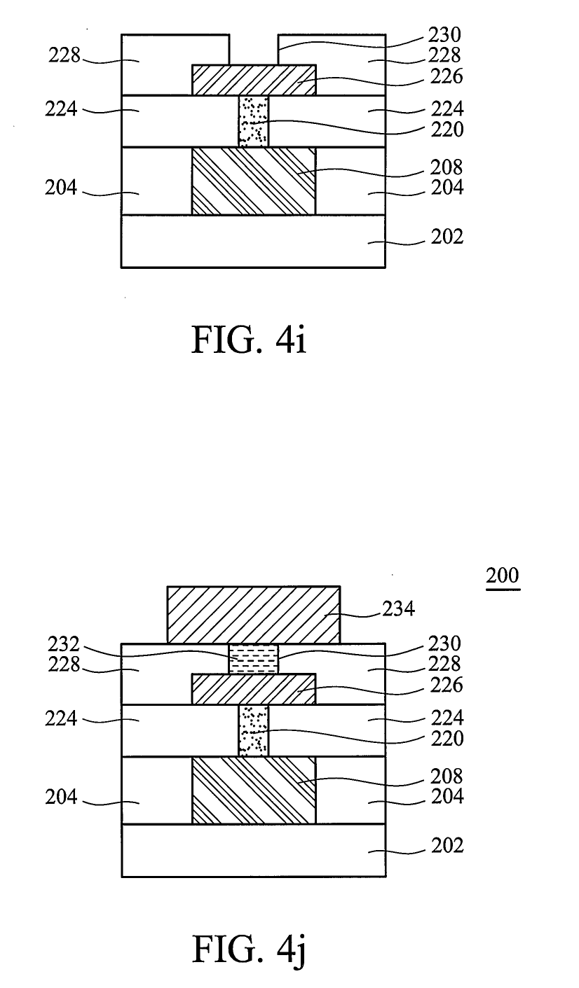

FIGS. 4a to 4j are sectional diagrams illustrating another embodiment of the manufacturing process of the phase-change memory element 200.

First, referring to FIG. 4a, a first dielectric layer 204 with a first opening 206 is formed on a substrate 202. Next, a metal layer is filled into the first opening 206 serving as a first electrode 208. Particularly, the substrate 202 can be a substrate employed in a semiconductor process, such as a silicon substrate. The substrate 202 can be a substrate comprising a complementary metal oxide semiconductor (CMOS) circuit, isolation structure, diode, or capacitor. The accompanying drawings show the substrate 102 in a plain rectangle in order to simplify the illustration. The first dielectric layer 204 can be silicon-containing compound, such as silicon nitride or silicon oxide. Suitable material for the first electrode can be Al, W, Mo, TiN, or TiW.

Next, referring to FIG. 4b, a first conducting layer 210, a second dielectric layer 212, a bottom anti-reflective coating 214, and a photoresist layer 216 are subsequently formed on the substrate 202. In this embodiment, suitable material for the first conducting layer 210 can be W, TiN, TiAlN, Ta, TaN, poly-Si, TiSiN, TaSiN, or combinations thereof; the second dielectric layer 110 serving as a hard mask layer can be a silicon-containing compound, such as silicon nitride or silicon oxide. In some embodiments of the invention, the second dielectric layer 110 is not required.

Next, referring to FIG. 4c, the photoresist layer 216 is patterned by a photolithography process and then trimmed by a trimming process to form a photoresist pillar 218 with a diameter of not more than 100 nm. It should be noted that, the photoresist pillar 218 is formed directly above the first electrode 208. According to the invention, the trimming process is not limited to a certain process, and can be a dry trimming process (such as plasma trimming process) or a solution trimming process.

Next, referring to FIG. 4d, the second dielectric layer 212 is etched to form a second dielectric pillar 222 with the photoresist pillar 218 as a mask, wherein the diameter of the second dielectric pillar 222 is not more than 100 nm. In this step, the photoresist pillar 218 and bottom anti-reflective coating 214 are removed by simultaneous etching. Specifically, the second dielectric pillar 222 is formed directly above and contacts the first electrode 208.

As a feature and a key aspect, the photoresist layer is patterned by a photolithography process and trimmed by a trimming process, resulting in a photoresist pattern with a diameter less than the resolution limit of photolithography process. The, second dielectric layer 212 is then etched with the reduced photoresist pattern as a mask, obtaining a second dielectric pillar 222.

Next, referring to FIG. 4e, the first conducting layer 210 is etched with the second dielectric pillar 222 as a mask to form a conducting pillar 220 directly above the first electrode 208 and directly contact therewith. It should be noted that the obtained conducting pillar 220 can be further trimmed by a trimming process in order to further reduce the diameter thereof, resulting in reduced contact area between the sequentially formed phase-change layers and the conducting pillar 220. According to the invention, the diameter of the conducting pillar 220 is not more than 100 nm.

Next, referring to FIG. 4f, a third dielectric layer 224 is formed on the substrate 202, completely covering the conducting pillar 220. Next, referring to FIG. 4g, the third dielectric layer 224 is planarized to expose the top surface of the conducting pillar 220, wherein the planarization can be chemical mechanical polishing. The third dielectric layer 224 can be silicon-containing compound, such as silicon nitride or silicon oxide.

Next, referring to FIG. 4h, a phase-change layer 226 is formed on the third dielectric layer 224 to directly contact and electrically connect to the top surface of the conducting pillar 220. The phase-change layer can comprise In, Ge, Sb, Te or combinations thereof, such as GeSbTe or InGeSbTe.

Next, referring to FIG. 4i, a fourth dielectric layer 228 is formed on the third dielectric layer 224 and the phase-change layer 226, wherein the fourth dielectric layer 228 having a second opening 230 exposes the top surface of the phase-change layer 226. The fourth dielectric layer 228 can be a silicon-containing compound, such as silicon nitride or silicon oxide.

Next, referring to FIG. 4j, a second conducting layer 232 is formed on and fills the second opening 230, electrically connecting the phase-change layer 226. Finally, a second electrode 234 is formed to electrically connect the second conducting layer 232. Suitable material for the second electrode 234 can be Al, W, Mo, TiN, or TiW. The second conducting layer 232 can be W, TiN, TiAlN, Ta, TaN, poly-Si, TiSiN, TaSiN, or combinations thereof.

The phase-change memory element of the invention is fabricated by photolithography and trimming processes, thus reducing the contact area between the phase-change layer and the heating electrode. It should be noted that the heater electrode (conducting pillar) can have a diameter less than the resolution limit of photolithography process. As a result, an operating current for a state conversion of the phase-change material pattern may be reduced so as to decrease a power dissipation of the phase-change memory device. In addition, because the operating current decreases, the sizes of other discrete devices (e.g., MOS transistors) of the phase-change memory device may also be decreased. Thus, the phase-change memory device may be suitable for high integration.

While the invention has been described by way of example and in. terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A phase-change memory element, comprising
a first dielectric layer with a first opening formed on a substrate;
a first electrode filled into the first opening;
a second dielectric layer formed on the first electrode;
a first conducting layer formed on the sidewalls of the second dielectric layer, electrically connecting the first electrode;
a third dielectric layer formed on the substrate, exposing the top surface of the first conducting layer;
a phase-change layer formed on the third dielectric layer and directly contacts to the top surface of the first conducting layer;
a fourth dielectric layer, having a second opening exposing the top surface of the phase-change layer, formed on the third dielectric layer and the phase-change layer; and
a second conducting layer filled into the second opening, electrically connecting to a second electrode.

2. The phase-change memory element as claimed in claim 1, wherein the second dielectric layer comprises a second dielectric pillar.

3. The phase-change memory element as claimed in claim 1, further comprising a fifth dielectric layer covering the sidewalls of the first conducting layer, exposing the top surface of the first conducting layer.

4. The phase-change memory element as claimed in claim 2, wherein the diameter of the second dielectric pillar is not more than 100 nm.

5. The phase-change memory element as claimed in claim 1, wherein the substrate comprises a complementary metal oxide semiconductor (CMOS) circuit.

6. The phase-change memory element as claimed in claim 1, wherein the first dielectric layer comprises a silicon-containing compound.

7. The phase-change memory element as claimed in claim 1, wherein the first dielectric layer comprises a silicon oxide or silicon nitride.

8. The phase-change memory element as claimed in claim 1, wherein the first electrode comprises Al, W, Mo, TiN, TiW, or combinations thereof.

9. The phase-change memory element as claimed in claim 1, wherein the first conducting layer comprises W, TiN, TiAlN, Ta, TaN, poly-Si, TiSiN, TaSiN, or combinations thereof.

10. The phase-change memory element as claimed in claim 1, wherein the first conducting layer comprises Al, W, Mo, TiN, TiW, or combinations thereof.

11. The phase-change memory element as claimed in claim 1, wherein the second dielectric layer comprises a silicon-containing compound.

12. The phase-change memory element as claimed in claim 1, wherein the phase-change layer comprises In, Ge, Sb, Te or combinations thereof.

13. The phase-change memory element as claimed in claim 1, wherein the phase-change layer comprises GeSbTe or InGeSbTe.

14. The phase-change memory element as claimed in claim 1, wherein the third dielectric layer comprises a silicon-containing compound.

15. The phase-change memory element as claimed in claim 1, wherein the fourth dielectric layer comprises a silicon-containing compound.

16. The phase-change memory element as claimed in claim 1, wherein the second electrode comprises Al, W, Mo, TiN, TiW, or combinations thereof.

17. The phase-change memory element as claimed in claim 1, wherein the second conducting layer comprises W, TiN, TiAlN, Ta, TaN, poly-Si, TiSiN, TaSiN, or combinations thereof.

18. The phase-change memory element as claimed in claim 1, wherein the first conducting layer has a thickness of less than 50 nm.

19. A method of fabricating a phase-change memory element, comprising:
providing a substrate;
forming a first dielectric layer with a first opening on the substrate;
forming a first electrode filled into the first opening;
forming a second dielectric pillar on the first electrode;
conformably forming a first conducting layer on the substrate to cover the sidewalls and top surface of the second dielectric layer;
etching the first conducting layer by anisotropic etching, exposing the top surface of the second dielectric pillar;
forming a third dielectric layer on the substrate;
subjecting the third dielectric layer to a planarization process, exposing the top surface of the first conducting layer;
forming a phase-change layer on the third dielectric layer, wherein the phase-change layer directly contacts to the top surface of the first conducting layer;
forming a fourth dielectric layer, having a second opening exposing the top surface of the phase-change layer, on the third dielectric layer and the phase-change layer;
forming a second conducting layer filled into the second opening, electrically connecting the phase-change layer; and
forming a second electrode electrically connecting the second conducting layer.

20. The method as claimed in claim 19, wherein the steps for forming the second dielectric pillar comprises:
forming a second dielectric layer and a photoresist layer on the substrate;
subjecting the photoresist layer to a trimming process to form a photoresist pillar above the first electrode; and
etching the second dielectric layer with the photoresist pillar as mask.

21. The method as claimed in claim 19, wherein the substrate comprises a complementary metal oxide semiconductor (CMOS) circuit.

22. The method as claimed in claim 20, further comprising forming a bottom anti-reflective coating between the second dielectric layer and the photoresist layer.

23. The method as claimed in claim 20, wherein the trimming process comprising dry trimming process or solution trimming process.

24. The method as claimed in claim 19, after conformably forming the first conducting layer, further comprising conformably forming a fifth dielectric layer on the first conducting layer.

25. The method as claimed in claim 19, wherein the first conducting layer has a thickness of less than 50 nm.

26. The method as claimed in claim 19, wherein the diameter of the second dielectric pillar is not more than 100 nm.

27. A method of fabricating a phase-change memory element, comprising:
providing a substrate;
forming a first dielectric layer with a first opening on the substrate;
forming a first electrode filled into the first opening;
forming a conducting pillar on the first electrode via a second dielectric layer;
forming a third dielectric layer on the substrate;
subjecting the third dielectric layer to a planarization process, exposing the top surface of the conducting pillar;
forming a phase-change layer on the third dielectric layer, wherein the phase-change layer directly contacts to the top surface of the conducting pillar;
forming a fourth dielectric layer, having a second opening exposing the top surface of the phase-change layer, on the third dielectric layer and the phase-change layer;
forming a second conducting layer filled into the second opening, electrically connecting the phase-change layer; and
forming a second electrode electrically connecting the second conducting layer.

28. The method as claimed in claim 27, wherein the steps for forming the conducting pillar via a second dielectric layer comprises:
forming a first conducting layer, the second dielectric layer, and a photoresist layer on the substrate;
subjecting the photoresist layer to a trimming process to form a photoresist pillar above the first electrode;
etching the second dielectric layer with the photoresist pillar as mask to form a second dielectric pillar; and
etching the first conducting layer with the second dielectric pillar as mask to form a conducting pillar.

29. The method as claimed in claim 27, wherein the substrate comprises a complementary metal oxide semiconductor (CMOS) circuit.

30. The method as claimed in claim 28, further comprising forming a bottom anti-reflective coating between the second dielectric layer and the photoresist layer.

31. The method as claimed in claim 28, wherein the trimming process comprising dry trimming process or solution trimming process.

32. The method as claimed in claim 27, wherein the second dielectric layer comprises a hard mask layer.

33. The method as claimed in claim 28, wherein the steps for forming the conducting pillar comprises:
etching the first conducting layer with the second dielectric layer as a mask; and
subjecting the etched first conducting layer to a trimming process to form the conducting pillar.

34. The method as claimed in claim 27, wherein the diameter of the conducting pillar is not more than 100 nm.
